(19) United States
(12) Patent Application Publication
(10) Pub. No.: US 2008/0030250 A1
(43) Pub. Date: Feb. 7, 2008

(54) FLIP-FLOP CIRCUIT

(75) Inventors: Shinji Furuichi, Maibara-city (JP); Satoru Sekine, Anpachi-Gun (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 11/693,146

(22) Filed: Mar. 29, 2007

(30) Foreign Application Priority Data
Mar. 31, 2006 (JP) 2006-097765
Sep. 25, 2006 (JP) 2006-258750
Jan. 25, 2007 (JP) 2007-015287

(51) Int. Cl. H03K 3/356; H03K 3/00

(52) U.S. Cl. 327/212; 327/199

(57) ABSTRACT

A pair of transistors receive the input of signals of input data and the inverted input data. An activation circuit, which is provided between the pair of transistors and fixed potential, activates the pair of transistors in a conduction state. A clock control circuit receives a clock signal and sets the activation circuit to a conduction state for a predetermined period starting from an edge timing of the clock signal. The activation circuit includes a first activation transistor and a second activation transistor which are connected in cascade with each other. The clock control circuit turns on both the first activation transistor and the second transistor for the predetermined period starting from the edge timing of the clock signal, and turns off at least one of the first activation transistor and the second activation transistor for a period other than the predetermined period.

### BACKGROUND OF THE INVENTION

1. Field of the Invention

The present invention relates to a flip-flop circuit that latches inputted data.

2. Description of the Related Art

A reduction in power consumption is required for an LSI (Large Scale Integration) circuit mounted on battery-operated equipment represented by mobile devices. As described FIG. 2 in Reference (1) in the following Related Art List, 20% to 45% of power consumed in the an LSI circuit is consumed as power consumed by the charging and discharging of capacitance by clock signals. Thus, the reduction in power consumed by the charging and discharging will be effective.

The power consumed by the charging and discharging of clock signals is proportional to the square of supply voltage. In this connection, to reduce the power consumed by the charging and discharging of clock signals, a method has been proposed where the supply voltage of a clock buffer is lowered and the amplitude of clock signals is reduced. Here, if the supply voltage for all elements in a circuit is lowered, a performance degradation due to an increase in delay time may occur. However, if the reduced supply voltage is supplied to the clock buffer alone, an increase in delay time is limited to the clock buffer alone. This can reduce the power consumed by the entire LSI circuit without deteriorating a chip performance. This is because the increase in delay time is limited to the clock buffer only.

As a method for reducing the power consumed in an LSI circuit mounted on equipment represented by mobile devices, a method has been proposed where the amplitude of a clock signal that consumes a large portion of the entire power consumption is set smaller than that of the supply voltage so as to operate the LSI circuit.

FIG. 1 is a circuit diagram showing a structure of a master-slave type flip-flop 1000, operating with a low-amplitude clock, disclosed in Reference (2). The flip-flop 1000 receives the input of a low-amplitude clock CLK and input data D, and outputs output data Q and inverted output data QN. The flip-flop 1000 includes a clock control circuit 100, a master latch circuit 120 and a slave latch circuit 130.

The clock control circuit 110 includes an inverter INV1. A voltage lower than the supply voltage is applied to the inverter INV1. The inverter inverts low-amplitude clock CLK inputted to the flip-flop 1000 so as to generate a low-amplitude inverted clock CLKb. The clock control circuit 110 outputs the low-amplitude clock CLK to the master latch circuit 120. Also, the clock control circuit 110 outputs the low-amplitude inverted clock CLKb to the slave latch circuit 130.

When the low-amplitude clock CLK goes high, the master latch circuit 120 becomes activated, and input data are fed to the master latch circuit 120. When the low-amplitude inverted clock CLKb goes high, the slave latch circuit 130 becomes activated, and the data taken in by the master latch circuit 120 are fed to the slave latch circuit 130. The slave latch circuit 130 outputs the data taken in when the slave latch circuit 130 is activated, as output data Q, and outputs data obtained by inverting the output data Q, as inverted output data QN.

In the flip-flop 1000, the master latch circuit 120 performs an activation control by a transistor M3 included in the master latch circuit 120. The slave latch circuit 130 performs an activation control by a transistor M6 included in the slave latch circuit 130. The transistor M3 and the transistor M6 are each an N-channel MOSFET (Metal Oxide Semiconductor Field Effect Transistor). When gate terminals thereof are at ground levels, they are completely turned off, so that the configuration of the master latch circuit 120 and the slave latch circuit 130 is such that unwanted current does not flow in an inactive state.

### RELATED ART LIST

(1) Takayasu Sakurai, Hiroshi Kawaguchi and Tadahiro Kuroda, “Low-Power CMOS Design through Vth Control and Low-Swing Circuits”, ISLPED, 1997, International Symposium on Low Power Electronics and Design, pp. 1-6
(2) Young-Su Kwon, Bong-il Park, In-Cheol Park, and Chong-Min Kyung, “A New Single-Clock Flip-Flop for Half-Swing Clocking”, Proc. Of ASP-DAC '99, pp. 117-121

In the flip-flop 1000 shown in FIG. 1, the master latch circuit 120 is constantly activated while the low-amplitude clock CLK is high. Thus during this period the input data D needs to be held outside in order that the input data do not vary, which causes a problem of increased hold time.

Since the slave latch circuit is activated by an inverted clock signal in Reference (2), a problem arises where a delay time until the data will be outputted is longer. Also, the master latch circuit is constantly activated while the low-amplitude clock is high. Thus, if a level transition occurs during this period, the master latch circuit will operate, thus causing a problem where unwanted power is consumed then.

### SUMMARY OF THE INVENTION

The present invention has been made in view of the foregoing circumstances and a general purpose thereof is to provide a flip-flop circuit that operates with a reduced power consumption. An advantage of the present invention is to provide a flip-flop circuit with a short hold time.

One embodiment of the present invention relates to a flip-flop circuit. This flip-flop circuit includes a latch circuit which latches input data based on a first clock, wherein the latch circuit takes in the input data in a period of a phase difference between the first clock and a second clock whose phase differs from that of the first clock.

The “first clock” and the “second clock” may be in-phase with each other or in reverse phase with each other. In the case of in-phase, the input data may be taken in either in a period during which the first clock is high and the second clock is low or in a period during which the first clock is low and the second clock is high. In the case of reverse phase, the input data may be taken in either in a period during which the first clock is high and the second clock is high or in a period during which the first clock is low and the second clock is low.

According to this embodiment, the latch circuit takes in the input data during a phase difference period. Hence, even if the input data transits during a period other said period, no signal transition will propagate within the flip-flop circuit, so that unwanted operation is suppressed and therefore the power consumption can be reduced.

The latch circuit may include a pair of transistors to which the input data and a signal obtained by inverting the input data are inputted. The pair of transistors may be activated in the period of a phase difference. According to this embodiment, even if the input data transits during a period other said period, no signal transition will propagate within the flip-flop circuit. As a result, unwanted operation is suppressed and therefore the power consumption can be reduced.

Another embodiment of the present invention relates to a flop-flop circuit. This flip-flop circuit includes: a first latch circuit which latches input data based on a first clock; and a second latch circuit which latches the data latched by the first latch circuit and which generates output data, wherein the first latch circuit is activated in a period of a phase difference between the first clock and a second clock whose phase differs from that of the first clock, and takes in the input data, and wherein the second latch circuit latches the data latched by the first latch circuit at the time when the first latch circuit is inactive.

According to this embodiment, the first latch circuit takes in the input data during a period of a phase difference. Thus, even if the input data transits during a period other said period, no signal transition will propagate within the flip-flop circuit. As a result, unwanted operation is suppressed and therefore the power consumption can be reduced. Also, the output timing can be controlled by the second latch circuit.

The flip-flop circuit may further include a control circuit which includes a plurality of stages of inverters connected in series with each other wherein the first clock is inputted to a first-stage inverter and an output of a final-stage inverter is outputted as the second clock. Thereby, the delay time of the clock control circuit can be determined by the drive capability of inverters or the number of inverters, so that the clock control circuit can be designed with ease.

According to another embodiment of the present invention, there is provided a flip-flop circuit for latching input data based on a clock signal. This flip-flop circuit comprises: a pair of transistors which receive an input of the input data and a signal of the reversed input data; an activation circuit which activates the pair of transistors in a conduction state; and a control circuit which receives the clock signal and sets the activation circuit to a conduction state for a predetermined period starting from an edge timing of the clock signal.

According to this embodiment, the pair of transistors are activated only for a predetermined period from an edge timing of the clock signal. Thus, even if the input data transit during a period other said period, no signal transition will propagate within the flip-flop circuit. As a result, unwanted operation is suppressed and therefore the power consumption can be reduced.

The activation circuit may include a first activation transistor and a second activation transistor which are connected in cascade with each other. The control circuit may turn on both the first activation transistor and the second transistor for a predetermined period starting from an edge timing of a clock signal, and may turn off at least one of the first activation transistor and the second activation transistor for a period other than the predetermined period.

In such a case the activation circuit is in a conduction state for a period during which both the first activation transistor and the second are on, so that the pair of transistors can be activated.

The control circuit may include a delay circuit which delays the clock signal by a predetermined delay time. An on-off of one of the first activation transistor and the second activation transistor may be associated with the clock signal, and an on-off of the other thereof may be associated with the delayed clock signal.

The delay circuit may include a plurality of stages of inverters. In such a case, for a period starting from a positive edge timing of a clock signal and lasting until a delay time has elapsed, an output of the plurality of stages of inverters and the original clock signal can turn on the first activation transistor and the second activation transistor simultaneously.

A narrower range may be specified by setting the level of a second supply voltage lower than the level of a first supply voltage supplied to the flip-flop circuit, and second supply voltage may be supply to the delay circuit.

In this case, the electric power consumed by the charging and discharging by clock signals is reduced, so that the power consumed by the entire circuitry can be reduced.

It is to be noted that any arbitrary combination of the above-described structural components and expressions converted among a method, an apparatus and so forth are all effective as and encompassed by the present embodiments.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a circuit diagram showing a structure of a conventional flip-flop, operating with a low-amplitude clock, according to a conventional practice;

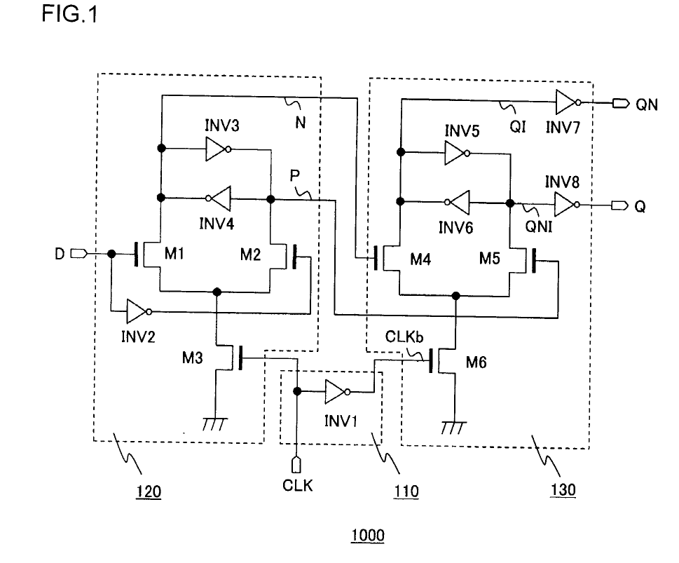

FIG. 2 is a circuit diagram showing a structure of a flip-flop according to a first embodiment of the present invention;

FIG. 3 is a sequence diagram showing an operation of a flip-flop according to a first embodiment of the present invention;

FIG. 4 is a circuit diagram showing a structure of a flip-flop for low-amplitude clocks according to a first modification of a first embodiment of the present invention;

FIG. 5 is a sequence diagram showing an operation of a flip-flop according to a first modification of a first embodiment of the present invention;

FIG. 6 is a circuit diagram showing a structure of a flip-flop according to a second modification of a first embodiment;

FIG. 7 is a circuit diagram showing a structure of a flip-flop circuit according to a second embodiment of the present invention;

FIG. 8 is a timing chart showing an operating state of a flip-flop circuit of FIG. 7;

FIG. 9 is a circuit diagram showing a structure of a flip-flop circuit according to a first modification of a second embodiment of the present invention;

FIG. 10 is a circuit diagram showing a structure of a flip-flop circuit according to a second modification of a second embodiment of the present invention;

FIG. 11 is a circuit diagram showing a structure of a flip-flop circuit according to a modification of FIG. 9;

FIG. 12 is a circuit diagram showing a structure of a flip-flop circuit according to a modification of FIG. 7 and FIG. 9;

FIG. 13 is a circuit diagram showing a structure of a flip-flop circuit according to a modification of a flip-flop circuit shown in FIG. 10; and

FIG. 14 is a circuit diagram showing a structure of a flip-flop circuit according to a modification of flip-flop circuits shown in FIG. 7 and FIG. 10.

### DETAILED DESCRIPTION OF THE INVENTION

With reference to the Figures, the invention will now be described based on the following preferred embodiments which do not intend to limit the scope of the present invention but exemplify the invention. The same or equivalent components, members and processings shown in Figures are given the identical reference numerals and the repeated description thereof will be omitted as appropriate. All of the features and the combinations thereof described in the embodiments are not necessarily essential to the invention.

### First Embodiment

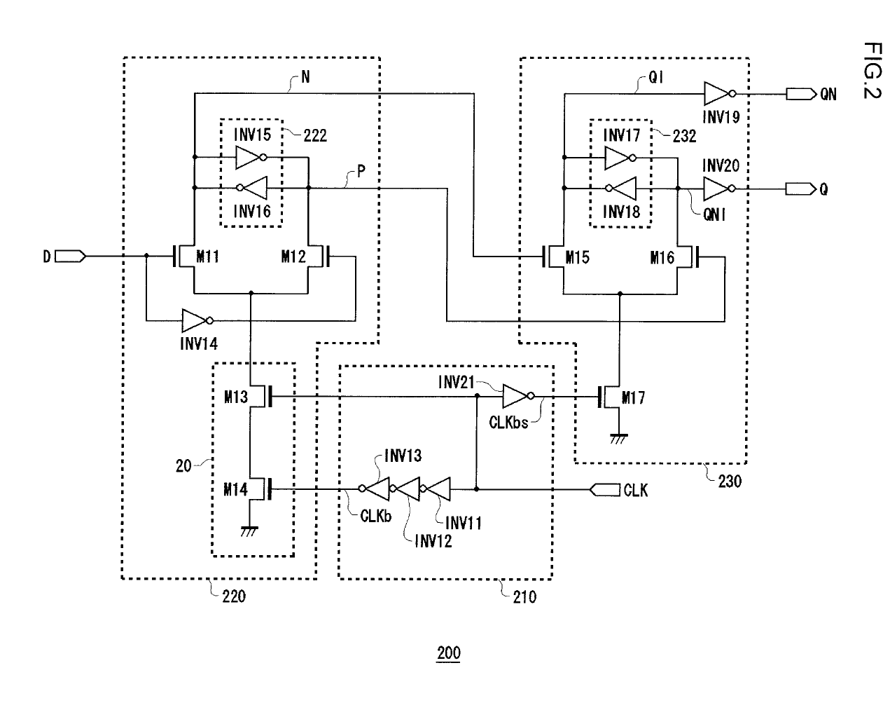

FIG. 2 is a circuit diagram of a flip-flop 200 according to a first embodiment of the present invention. A low-amplitude clock CLK and input data D are inputted to a flip-flop 200. The flip-flop 200 outputs output data Q and inverted output data QN. The low-amplitude clock CLK is a clock that oscillates at a voltage whose level is lower than a supply voltage. The flip-flop 200 takes in the input data D in synchronism with the low-amplitude clock CLK, outputs the thus taken-in data as the output data Q and outputs the inverted data thereof as inverted output data QN. The flip-flop 200 includes a clock control circuit 210, a master latch circuit 220 and a slave latch circuit 230.

The clock control circuit 210 includes an inverter INV 11, an inverter INV12 and an inverter INV13, which are connected in series to each other. An input terminal of the inverter INV13 is connected to the low-amplitude clock CLK. A voltage lower than a supply voltage is applied to the inverter INV11, the inverter INV12 and the inverter INV13. The low-amplitude clock CLK inputted to the inverter INV11 is delayed by these three inverters INV11, INV12 and INV13 and is thus further inverted, so that a low-amplitude inverted clock CLKb is generated.

The clock control circuit 210 outputs the low-amplitude clock CLK and the low-amplitude inverted clock CLKb to the master latch circuit 220. The clock control circuit 210 further includes an inverter INV21. And an input terminal of the inverter INV21 is connected to the low-amplitude clock CLK and an output terminal of the inverter INV21 is connected with a gate terminal of a transistor M17. The clock control circuit 210 outputs a low-amplitude inverted clock CLKbs for use in the slave latch circuit 230 (hereinafter referred to as “slave low-amplitude inverted clock CLKbs”) to the slave latch circuit 230.

In the first embodiment, a case where three inverters are provided for the clock control circuit 210 is exemplified here. However, it suffices if an odd number of inverters are provided in series. In such a case, a structure may be such that the low-amplitude clock CLK inputted to the flip-flop 200 is inverted to generate the low-amplitude inverted clock CLKb. In this case, as will be discussed later, the number of inverters is preferably a minimum number thereof such that the low-amplitude clock CLK can be delayed for a duration of time sufficient for the master latch circuit 220 to become activated and taken in the input data D.

The master latch circuit 220 becomes activated when the low-amplitude clock CLK changes from a low level to a high level, and then takes in the input data D. The master latch circuit 220 includes a transistor M11, a transistor M12, a transistor M13, a transistor M14, an inverter INV14, an inverter INV15, and an inverter INV16. The transistor M13 and the transistor M14 constitute an activation circuit 20. The transistor M11, the transistor M12, the transistor M13 and the transistor M14 may be each an N-channel MOSFET.

In the master latch circuit 220, the input data D are connected to a gate terminal of the transistor M11 and an input terminal of the inverter INV14. An output terminal of the inverter INV14 is connected with a gate terminal of the transistor M12. A source terminal of the transistor M11 and a source terminal of the transistor M12 are both connected to a drain terminal of the transistor M13.

A drain terminal of the transistor M14 is connected to a source terminal of the transistor M13, and a source terminal of the transistor M14 is grounded. The low-amplitude clock CLK is inputted to a gate terminal of the transistor M13, and The low-amplitude inverting clock CLKb is inputted to a gate terminal of the transistor M14.

A master-side data hold circuit 222 is provided between a drain terminal of the transistor M11 and a drain terminal of the transistor M12. Data retrieved in the master latch circuit 220 are stored in the master-side data hold circuit 222. The master-side data hold circuit 222 includes an inverter INV15 and an inverter INV16. An input terminal of the inverter INV15 and an output terminal of the inverter INV16 are connected with the drain terminal of the transistor M11, whereas an output terminal of the inverter INV15 and an input terminal of the inverter INV16 are connected with the drain terminal of the transistor M12.

An activation control of the master latch circuit 220 is performed by the transistor M13 and the transistor M14. That is, when the low-amplitude clock CLK and the low-amplitude inverted clock CLKb both go high, both the transistor M13 and the transistor M14 turn on and the master latch circuit 220 is in an active state. When at least one of the low-amplitude clock CLK and the low-amplitude inverted clock CLKb goes low, either the transistor M13 or the transistor M14 turns off and the master latch circuit 220 is in an inactive state. At this time, since both the transistor M13 and the transistor M14 are N-channel MOSFETs, they will be completely turned off if the gate terminals of these transistors M13 and M14 go to the ground level. In this manner, the master latch circuit 220 is so structured that the unwanted current does not flow in the inactive states.

When the slave low-amplitude inverted clock CLKbs goes high, the slave latch circuit 230 becomes activated and the data retrieved in the master latch circuit 220 are fed to the slave latch circuit 230 and outputted therefrom. The slave latch circuit 230 includes a transistor M15, a transistor M16, a transistor M17, an inverter INV17, an inverter INV18, an inverter INV19, and an inverter INV20. The transistor M15, the transistor M16 and the transistor M17 are all N-channel MOSFETs.

In the slave latch circuit 230, a gate terminal of the transistor M15 is connected with the drain terminal of the transistor M11 by a signal line N. A gate terminal of transistor M16 is connected with the drain terminal of the transistor M12 by a signal line P. A source terminal of the transistor M15 and a source terminal of the transistor M16 are both connected to a drain terminal of the transistor M17. The low-amplitude clock CLK is inputted to the gate terminal of the transistor M17, and a source terminal of the transistor M17 is grounded.

A slave-side data hold circuit 232 is provided between a drain terminal of the transistor M15 and a drain terminal of the transistor M16. Data retrieved in the slave latch circuit 230 are stored in the slave-side data hold circuit 232. The slave-side data hold circuit 232 includes an inverter INV17 and an inverter INV18. An input terminal of the inverter INIV17 and an output terminal of the inverter INV18 are connected with the drain terminal of the transistor M15. An output terminal of the inverter INIV17 and an input terminal of the inverter INV18 are connected with the drain terminal of the transistor M16.

The drain terminal of the transistor M15 is also connected to an input terminal of the inverter INV19 by a signal line QI, and an output terminal of the inverter INV19 is connected to an inverted output data QN terminal. The drain of the transistor M16 is also connected to an input of the inverter INV20 by the signal line QNI, and an output terminal of the inverter INV20 is connected to an output Q terminal.

The activation control of the slave latch circuit 230 is performed by the transistor M17. That is, when the slave low-amplitude inverted clock CLKbs goes high, the transistor M17 turns on and the slave latch circuit 230 is activated. When the slave low-amplitude inverted clock CLKbs goes low, the transistor M17 turns off and the slave latch circuit 230 is in an inactive state. At this time, since the transistor M17 is an N-channel MOSFET, the transistor M17 will be completely turned off if the gate terminal of the transistors M17 goes to the ground level. In this manner, the slave latch circuit 230 is so structured that the unwanted current does not flow in the inactive states.

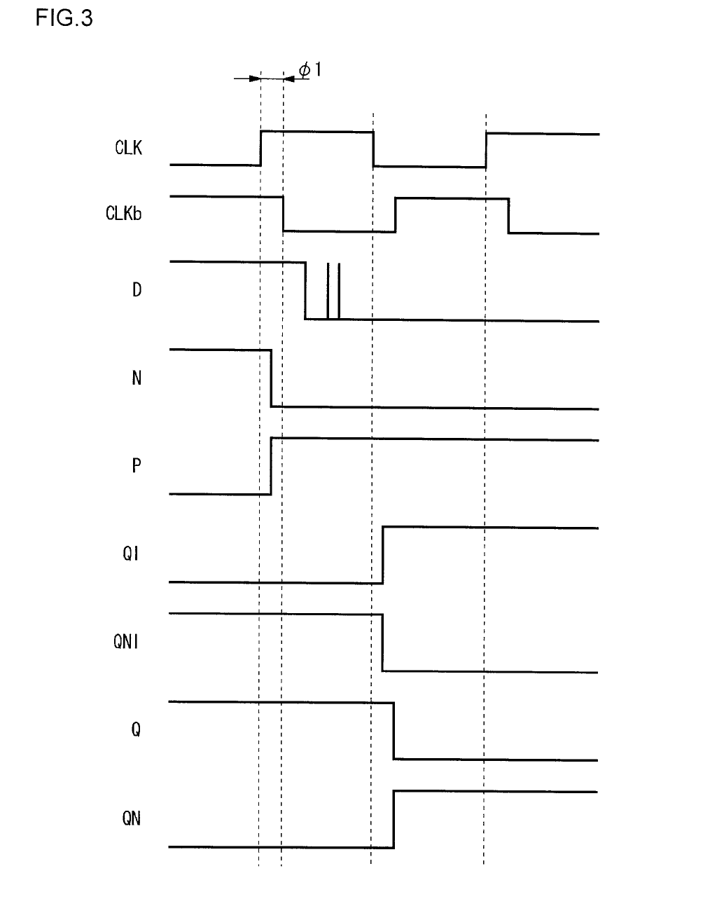

An operation of the flip-flop 200, structured as above, according to the first embodiment will now be described. FIG. 3 is a sequence diagram showing an operation of the flip-flop 200.

When the low-amplitude clock CLK inputted to the flip-flop 200 transits from low to high, the low-amplitude inverted clock CLKb transits from high to low with a delay corresponding to a delay time of the inverter INV11, the inverter INV12 and the inverter INV13. Thereby, a data retrieving period φ1 during which the low-amplitude clock CLK and the low-amplitude inverted clock CLKb are both high is generated.

In the data retrieving period φ1, the master latch circuit 220 is activated, and the input data D are fed to the master latch circuit 220. For instance, when the input data value is “1” (high) in the data retrieving period φ1, the master latch circuit 220 takes in the input data value of “1” with a result that the signal line N goes low and the signal line P goes high.

As the low-amplitude inverted clock CLKb transits from high to low and therefore the data retrieving period φ1 has terminated, the master latch circuit 220 shifts from an active state to an inactive state. If the master latch circuit 220 is in an inactive state with the value of input data D being varied, the master latch circuit 220 will not take in the input data D. Thus, the level at the signal line N and the signal P will not change, either.

On the other hand, when the low-amplitude clock CLK is low, the slave latch circuit 230 is in an active state. As a result, the slave latch circuit 230 then takes in the levels of the signal line N and the signal line P determined in the data retrieving period φ1. Thereby, the levels of the signal line QI and the signal line QNI are determined according to these levels of the signal line N and the signal line P. For instance, if it is determined in the data retrieving period φ1 that the signal line N is low and the signal line P is high, the signal line QI will be high and the signal QNI will be low.

Even when the low-amplitude CLK is high, the master latch circuit 220 is in an inactive state and the values of the signal line N and the signal line P do not change after the data retrieving period φ1. Thus, after the levels of the signal line QI and the signal line QNI have been determined according to the values of the signal line N and the signal line P at the completion of the data retrieving period φ1, these levels of the signal line QI and the signal line QNI do not change and therefore the values are determined as the thus determined level.

The signal levels of the signal line QI and the signal line QNI determined in the slave latch circuit 230 are inverted by the inverter INV19 and the inverter INV20, respectively, so as to be outputted as inverted output data QN and output data Q.

A description has been given of an operation and a structure of the flip-flop 200 according to an embodiment. According to the first embodiment, a structure is such that in the clock control circuit 210 the low-amplitude clock CLK is delayed and inverted by using an odd number of inverters so as to generate the low-amplitude inverted clock CLK. And the master latch circuit 220 becomes activated when the low-amplitude clock CLK and the low-amplitude inverted clock CLKb are both high, namely during the data retrieving period 41. As a result, such operations and advantageous effects as follows are achieved.

(1) Even when the slave latch circuit 230 is activated, the master latch circuit 220 is in an inactive state during periods other than a data read period φ1. As a result, no unwanted signal propagation occurs between the master latch circuit 220 and the slave latch circuit 230. Thereby, no unwanted power is consumed and therefore the power consumption can be suppressed.

(2) The duration of time in which the master latch circuit 220 becomes active is a delay time caused by an odd number of inverters provided in the clock control circuit 210. Thus, the hold time of the input data D can be determined by the delay time of this odd number of inverters alone. Hence, if a drive capability and/or the number of inverters in the clock control circuit 210 are determined so that this delay time is necessary and sufficient for the retrieving of the input data when the master latch circuit 220 becomes active, the hold time of the flip-flop 200 can be shortened.

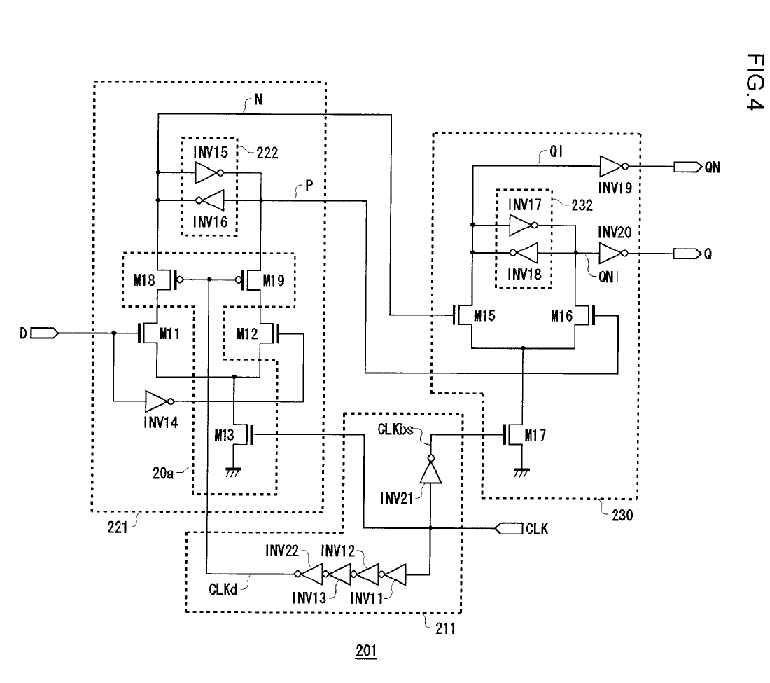

FIG. 4 is a circuit diagram of a flip-flop 201 according to a first modification of the first embodiment. The flip-flop 201 according to the first modification 201 includes a clock control circuit 211, a master latch circuit 221, and a slave latch circuit 230. The structure of the slave latch circuit 230 is the same as that of the flip-flop 200 shown in FIG. 2 and therefore the repeated explanation thereof is omitted here.

The clock control circuit 211 includes an inverter INV11, an inverter INV12, an inverter INV13 and an inverter INV22, which are connected in series with each other. An input terminal of the inverter INV11 is connected to a low-amplitude clock CLK the high level of which oscillates at a voltage level lower than the supply voltage. The low-amplitude clock CLK inputted to the inverter INV11 is delayed by four inverters INV11, INV12, INV13 and INV22. Also, a low-amplitude delayed clock CLKd that oscillates at a voltage, the low level of which is higher than the ground voltage, is generated by using a known level shift circuit.

The clock control circuit 211 outputs the low-amplitude clock CLK and the low-amplitude delayed clock CLKd to the master latch circuit 221. The clock control circuit 211 further includes an inverter INV21. And an input terminal of the inverter INV21 is connected to the low-amplitude clock CLK and an output terminal of the inverter INV21 is connected with a gate terminal of a transistor M17. The clock control circuit 211 outputs a low-amplitude inverted clock CLKbs for use in the slave latch circuit 230 (hereinafter referred to as “slave low-amplitude inverted clock CLKbs”) to the slave latch circuit 230.

In this modification, a case where four inverters are provided for the clock control circuit 211 is exemplified. However, it suffices if an even number of inverters are provided in series. In such a case, a structure may be such that the low-amplitude clock CLK inputted to the flip-flop 201 is delayed to generate the low-amplitude inverted clock CLKd. In this case, as will be discussed later, the number of inverters is preferably a minimum number thereof such that the low-amplitude clock CLK can be delayed for a duration of time sufficient for the master latch circuit 221 to become activated and taken in the input data D.

The master latch circuit 221 includes a transistor M11, a transistor M12, a transistor M18, a transistor M19, a transistor M13, an inverter INV14, an inverter INV15, and an inverter INV16. The transistor M13, the transistor M18 and the transistor M19 constitute an activation circuit 20a. The transistor M11, the transistor M12 and the transistor M13 are each an N-channel MOSFET, whereas the transistor M18 and the transistor M19 are each a P-channel MOSFET. The transistor M11 and the transistor M12 constitutes a pair of transistors, whereas the transistor M18 and the transistor M19 also comes in pair.

Hereinafter, for the master latch circuit 221 according to the first modification, the description involving common points with the master latch circuit 220 in the flip-flop 200 of FIG. 2 is omitted here, and a description will be given of points that differ therefrom. The transistor M14 is not used in the master latch circuit 221 according to the first modification. Accordingly, a source terminal of the transistor M13 is directly grounded.

A drain terminal of the transistor M11 is connected to a drain terminal of the transistor M18, whereas a drain terminal of the transistor M12 is connected to a drain terminal of the transistor M19. A master-side data hold circuit 222 is provided between a source terminal of the transistor M18 and a source terminal of the transistor M19. The aforementioned low-amplitude delay clock CLKd is inputted commonly to a gate of the transistor M18 and a gate terminal of the transistor M19.

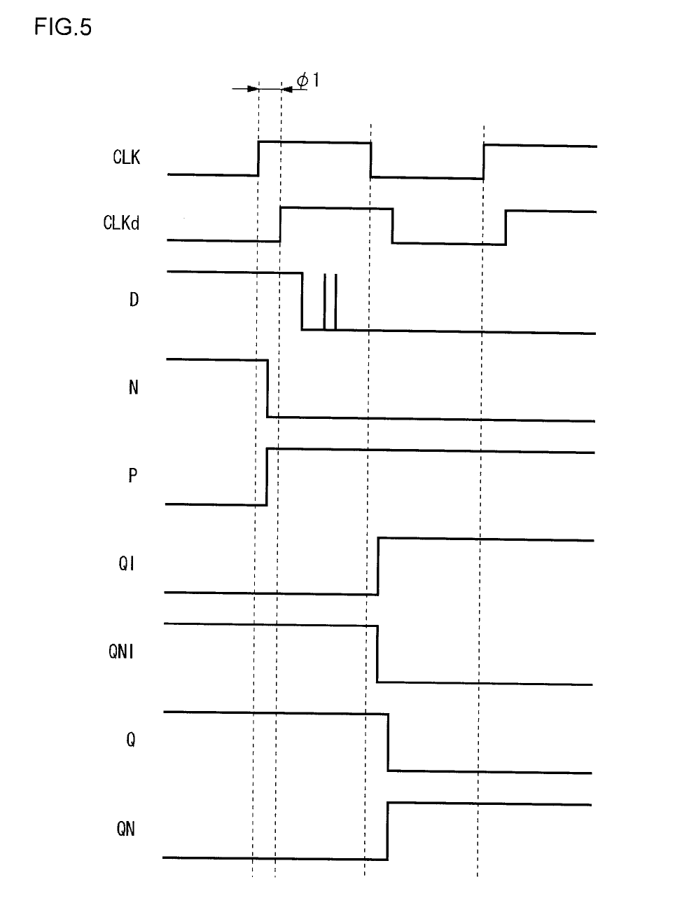

An operation of the flip-flop 201, structured as above, according to the first modification will now be described. FIG. 5 is a sequence diagram showing an operation of the flip-flop 201.

When the low-amplitude clock CLK inputted to the flip-flop 201 transits from low to high, the low-amplitude delayed clock CLKd transits from low to high with a delay corresponding to a delay time of the inverter INV11, the inverter INV12, the inverter INV13 and the inverter INV22. Thereby, a data retrieving period φ1 during which the low-amplitude clock CLK goes high and the low-amplitude delayed clock CLKd goes low is generated.

In the data retrieving period φ1, the master latch circuit 221 is activated, and the input data D are fed to the master latch circuit 221. For instance, when the value of the input data D is “1” (high) in the data retrieving period φ1, the master latch circuit 221 takes in the input data value of “1” with a result that the signal line N goes low and the signal line P goes high.

As the low-amplitude delayed clock CLKd transits from low to high and therefore the data retrieving period φ1 has terminated, the master latch circuit 220 shifts from an active state to an inactive state. If the master latch circuit 220 is in an inactive state with the value of input data D being varied, the master latch circuit 221 will not take in the input data D. Thus, the level at the signal line N and the signal P will not change, either. An operation of the slave latch circuit 230 is similar to that described in FIG. 3.

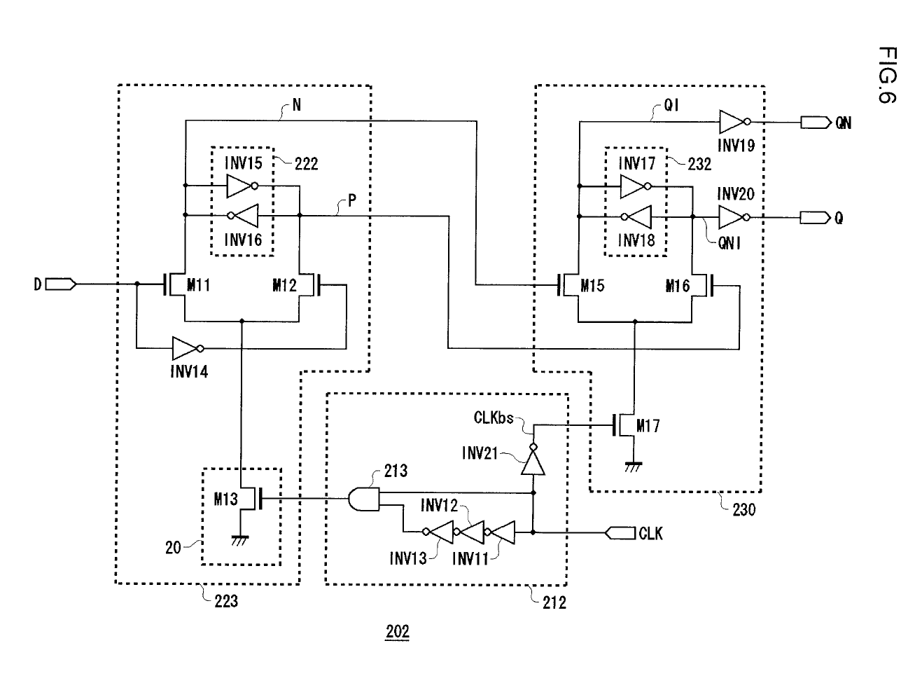

FIG. 6 is a circuit diagram of a flip-flop 202 according to a second modification of the first embodiment. The flip-flop 202 according to the second modification includes a clock control circuit 212, a master latch circuit 223, and a slave latch circuit 230. The structure of the slave latch circuit 230 is similar to that of the flip-flop 200 shown in FIG. 2 and therefore the repeated description thereof is omitted.

The structure of the clock control circuit 212 is such that an AND gate 213 is added to the clock control circuit 210 of FIG. 2. A low-amplitude clock CLK and a low-amplitude inverted clock CLKb outputted from the inverter INV13 are inputted to two input terminals of the AND gate 213, respectively. An output terminal of the AND gate 213 is connected to a gate terminal of the transistor M13. The AND gate 213 outputs a high level signal only if both the low-amplitude clock CLK and the low-amplitude inverted clock CLKb are both high. If at least one of the low-amplitude clock CLK and the low-amplitude inverted clock CLKb is low, the AND gate 213 will output a low level signal.

The structure of the master latch circuit 223 according to the second modification is such that the transistor M14 in the master latch circuit 220 shown in FIG. 2 is removed. Thus, the source terminal of the transistor M13 is directly grounded. An output signal of the AND gate 213 is inputted to the gate terminal of the transistor M13.

An operation of the flip-flop 202 according to the second modification is similar to that of the flip-flop 200 shown in FIG. 3.

The present invention has been described based on the first embodiment and modifications thereto. These embodiments and modifications are merely exemplary, and it is understood by those skilled in the art that other various modifications to the combination of each component and each process thereof are possible and that such modifications are also within the scope of the present invention.

For example, a structure for the flip-flop 200 may be such that either one or both of a set function of setting the output data Q to “1” and a reset function of setting the output data Q to “0” is/are provided. In such a case, in the master-side data hold circuit 222 or the slave-side data hold circuit 232, a structure may be such that a NAND circuit or NOR circuit is used instead of the inverter INV15, the inverter INV16, the inverter INV17 and the inverter INV18, and a set signal or reset signal is connected to one of input terminals of the NAND circuit or NOR circuit.

In the first embodiment, an example was shown where the transistors M11 to M17 are each an N-channel MOSFET, but they may be each a P-channel MOSFET. Then the supply voltage will be applied to the source terminals of the transistor M14 and transistor M17. In this case, the polarity of signal is reversed. Hence, the master latch circuit 220 is activated if both the low-amplitude clock CLK and the low-amplitude reversed clock CLKb are low. And the slave latch circuit 230 is activated if the low-amplitude clock CLK is high.

In a preferred embodiment, the low-amplitude clock CLK and the low-amplitude reversed clock CLKb may be set in a manner such that a narrower range of voltage between a second ground voltage higher than a first ground voltage supplied to the flip-flop circuit and a first supply voltage supplied to the flip-flop circuit is set and the second ground voltage is supplied to a delay circuit.

In the first embodiment, an example was shown where the low-amplitude clock is inputted as an input clock. However, a clock input having the same amplitude as the supply voltage may be inputted.

In the first embodiment, an example was shown where the output data Q and the inverted output data QN are available as the output of the flip-flop circuit 200. Instead, the output of the flip-flop circuit 200 may be only one of them.

### Second Embodiment

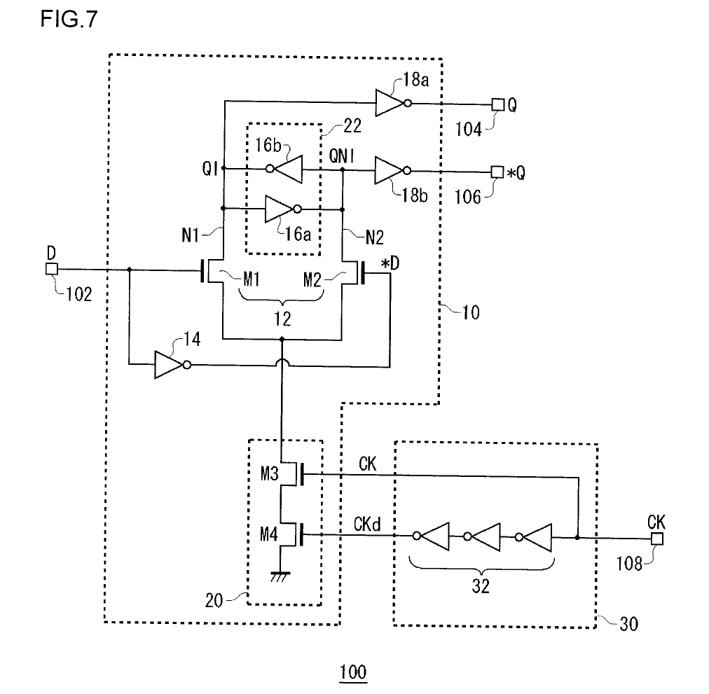

FIG. 7 is a circuit diagram showing a structure of a flip-flop circuit 100 according to a second embodiment of the present invention. As input/output terminals, the flip-flop circuit 100 includes an input terminal 102 to which input data D are inputted, an output terminal 104 from which an output signal Q is outputted, an inverted output terminal 106 from which an inverted output signal *Q is outputted, and a clock terminal 108 to which a clock signal CK is inputted. According to this second embodiment, the inversion of a given logical signal, namely its complementary level is denoted by*. This flip-flop circuit 100 latches the input data D based on the clock signal CK and then outputs the output signal Q and the inverted output signal *Q.

The flip-flop circuit 100 includes a latch circuit 10 and a clock control circuit 30.

The latch circuit 10 is a circuit for storing the input data D, and it includes a pair of transistors 12, an input inverter 14, internal inverters 16a and 16b, output inverters 18a and 18b, and an activation circuit 20.

The pair of transistors 12 has a structure including a first input transistor M1 and a second input transistor M2 which are each an N-channel MOSFET. The first input transistor M1 and the second input transistor M2 are connected in common with their source terminals. A gate terminal of the first input transistor M1 is connected to the input terminal 102, and the input data D is inputted to the gate of the first input transistor M1. The input signal *D which has been inverted by the input inverter INV14 is inputted to a gate terminal of the second input transistor M2. In an active state, the first input transistor M1 and the second input transistor M2 are turned on and off, in a complementary manner, according to the input signal D. A state where the pair of transistors 12 are active is a state where a path leading from a first fixed potential (power supply) to a second fixed potential (grounding) is capable of being electrically conducted. Hereinafter, the drain terminals of the first input transistor M1 and the second input transistor M2 will be denoted by internal nodes N1 and N2, respectively, and the signals appearing at the nodes N1 and N2 will be denoted by internal signals QI and QNI, respectively.

The drain terminal of the first input transistor M1 and the drain terminal of the second input transistor M2, namely the internal node N1 and the internal node N2, are connected with each other via the internal inverter 16a and the second internal inverter 16b which are connected in opposite direction to each other. The first internal inverter 16a and the second internal inverter 16b constitute a data hold circuit 22 and function as memory for storing the internal signals QI and QNI of the internal nodes N1 and N2 in a complementary manner.

The first output inverter 18a inverts the internal signal QI of the internal node N1 and then outputs it from the output terminal 104. The second output inverter 18b inverts the internal signal QNI of the internal node N2 and then outputs it from the inverted output terminal 106.

The activation circuit 20 is provided between the pair of transistors 12 and a ground potential which is a fixed potential. In a conduction state, the activation circuit 20 activates the pair of transistors 12. The activation circuit 20 includes a first activation transistor M3 and a second activation transistor M4 which are cascade-connected with each other. The first activation transistor M3 and the second activation transistor M4 are each an N-channel MOSFET. A drain terminal of the first activation transistor M3 is connected with the common source of the first input transistor M1 and the second input transistor M2 that constitute the pair of transistors 12. A source terminal of the first activation transistor M3 and a drain terminal of the second activation transistor M4 are connected with each other, and the source of the second activation transistor M4 is grounded. As both the first activation transistor M3 and the second activation transistor M4 turn on, they become conductive so as to activate the pair of transistor 12.

Upon receipt of the clock signal CK, the clock control circuit 30 sets the activation circuit 20 to a conduction state, for a predetermined retrieving period Tx from the timing of its positive edge. In the second embodiment, the control circuit 30 turns both the first activation transistor M3 and the second transistor M4 on during a period until the retrieving period Tx has elapsed from the timing of the positive edge, and turns off at least one of the first activation transistor M3 and the second activation transistor M4 in other periods.

Accordingly, the control circuit 30 has a structure which includes a delay circuit 32 that delays the clock signal CK by a predetermined delay time τ. An original clock signal CK and a delayed clock signal CKd are inputted to a gate terminal of the first activation transistor M3 and a gate terminal of the second activation transistor M4, respectively. By adjusting the delay time, a duration of time during which both the first activation transistor M3 and the second activation transistor M4 turn on, namely an activation period of the latch circuit 10 can be adjusted.

In the second embodiment, the delay circuit 32 is so configured that an inverter having an odd number of stages are included therein. While delaying the clock signal CK, the delay circuit 32 outputs the inverted clock signal CKd.

In a preferred embodiment, a narrower range of the clock signal CK is achieved by setting the level of a second supply voltage lower than the level of the first supply voltage supplied to the flip-flop circuit 100. Further, the second supply voltage is supplied to the delay circuit 32, and the inverter having an odd number of stages is run by this second supply voltage.

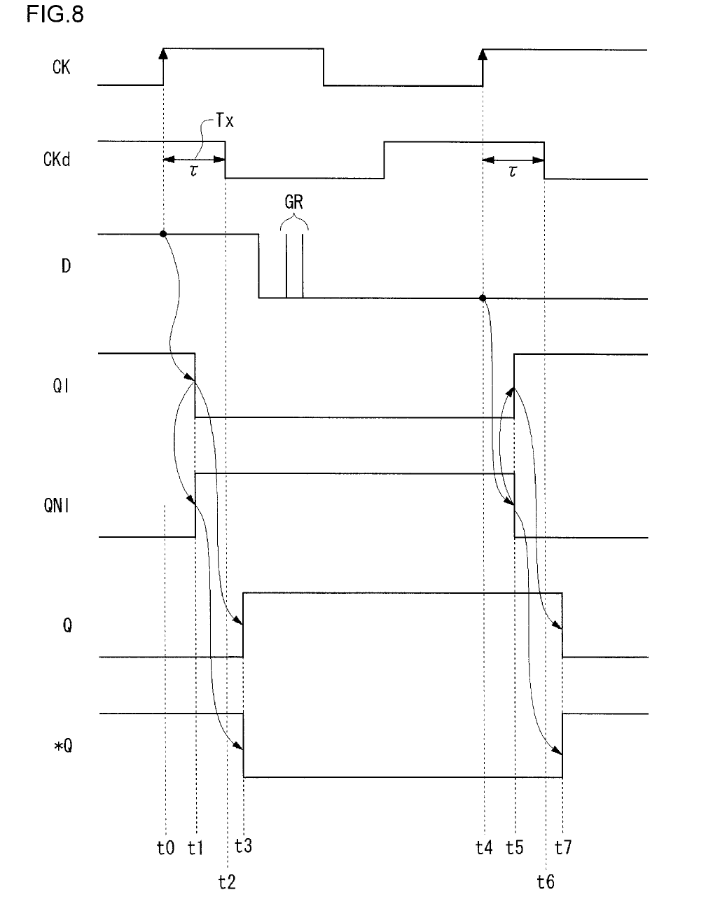

An operation of the flip-flop circuit 100 structured as above will now be described. FIG. 8 is a timing chart showing an operating state of the flip-flop circuit 100 shown in FIG. 7.

Before time t0, the clock signal CK is low and the inverted clock signal CKd is high. As the clock signal CK goes high at time t0, both the clock signal CK and the inverted clock signal CKd are high. Then both the first activation transistor M3 and the second activation transistor M4 in the activation circuit 20 turn on simultaneously, thus activating the latch circuit 100.

As both the first activation transistor M3 and the second activation transistor M4 turn on and therefore the activation circuit 20 becomes conductive, the drain terminal of the first activation transistor M3 and the source terminals of the first input transistor M1 and the second input transistor M2 are set to low levels.

As the latch circuit 10 is activated at time t0, the input signal D is fed thereto. Since the input signal D is high at time t0, the first input transistor M1 turns on and an internal signal QI of the drain terminal (internal node N1) of the first input transistor M1 transits to the same potential as the source thereof, namely, a low. A level transition of the internal signal QI is caused, by a finite length of delay time of each element, at t1 which comes after t0 at which the latch circuit 10 is activated.

As the internal signal QI transits to a low level at time t1, this signal is inverted by the internal inverter 16a and thereby the internal signal QNI transits to a high level. The internal signals QI and QNI are stored, by the internal inverters 16a and 16b, at a stable state of mutually complementary signal level.

As the internal signal QI transits from a high to a low at time t1, this signal is inverted by the inverter 18a and then the output signal Q transits from low to high. Since a delay also occurs in the first output inverter 18a, the output signal Q transits at time t3 which comes after time t1 at which a level transition of the internal signal QI occurs. Similarly, as a result of the level transition of the internal signal of QNI, the inverted output signal *Q transits from high to low at t3.

In this manner, with a positive edge of the clock signal CK at time t0, the latch circuit 10 can latch the input signal D of t0, and store the output signal Q at the same logical level as the input signal D and store the inverted output signal *Q at the complementary level of the output signal Q.

Here, the clock signal CKd which has been delayed and inverted by the delay circuit 32 transits from high to low at time t2 lagged by a delay time τ from time t0. As the clock signal CKd goes low, the second activation transistor M4 turns off, that is, the activation circuit 20 becomes nonconductive, and the latch circuit 10 is set inactive. Thus, in the circuit of FIG. 7, in a period starting from a positive edge of the clock signal CK and lasting until a delay time τ has elapsed, the clock signal CK and the delay clock signal CKd are both high and the retrieving period Tx is set. During this period, the first activation transistor M3 and the second activation transistor M4 in the activation circuit 20 turn on simultaneously and thereby the pair of transistors 12 are activated. Even when the pair of transistors 12 are set inactive, the signal levels of the internal signals QI and QNI are stored, by the inverters 16a and 16b, at a complementary level.

In the second embodiment, the delay time τ is set to a duration of time required for the input signal D to be stably stored as the internal signals QI and QNI after the pair of transistors 12 have been activated. That is, the delay time τ is set longer than the period of t0 to t1.

After time t2, the latch circuit 10 is set inactive. Thus, even if the input signal D transits from high to low, the transition will not be reflected in the output signal Q and the inverted output signal *Q. Besides the level transition of the input signal Q, if a glitch GR occurs as shown in FIG. 8, the transition will not be reflected in the internal signals QI and QNI. Thus, an unnecessary level transition does not occur. As a result, unnecessary power consumption can be reduced.

As, at time t4, the clock signal CK transits from low to high in the next cycle of the clock signal CK, both the first activation transition M3 and the second activation transistor M4 turn on and the latch circuit 10 is activated. At time t4 the input signal D is low, so that in an activation state the first input transistor M1 is off and the second input transistor M2 is on. As a result, the potential of the drain terminal of the second input transistor M2, namely the internal signal QNI, transits to a low level. Also, the internal signal QNI is inverted by the internal inverter 16b and the internal signal QI goes high (at t5).

Then the internal signals QI and QNI are inverted by the first and second output inverters 18a and 18b, respectively. As a result the output signal Q and the inverted output signal *Q transit to a low level and a high level, respectively (at time t7).

At t7 lagged by the delay time τ from time t4, the clock signal CKd transits from high to low, thus setting the latch circuit 10 inactive. Even if the pair of transistors 12 are set inactive, the signal levels of the internal signal QI and QNI will be held at a complementary level by the internal inverters 16a and 16b and the output signals Q and *Q will continue to be held, too.

As described above, by employing the flip-flop circuit 100 according to the second embodiment, the period during which the latch circuit 10 is active is set to a predetermined length of time Tx (=τ). This can prevent unwanted data transition from propagating within the flip-flop circuit 100, thus reducing the power consumed as a result of the unwanted level transition.

Also, by employing the flip-flop circuit 100 according to the second embodiment, two switches connected in series with each other are provided as the activation circuit 20. Thus, for a period only when both switches are on, the latch circuit 10 becomes active to retrieve the input data D. With this circuit configuration, there is no need to implement the structure having two stages of a master latch and a slave latch. Thus, the number of circuit elements required can be reduced. Since the flip-flop circuit 100 is configured by using a single latch circuit, the number of transistors that turn on and off to perform the latch operation can be reduced. Thus, the power consumption can be reduced. As a result, increase in circuit scale can be suppressed and, at the same time, power consumption can be reduced.

In the structure having two stages, the latch operation is performed in two stages of a master latch and a slave latch, so that the time between when the input data D are retrieved until it has been reflected in the output data Q will be longer. In contrast thereto, according to the flip-flop circuit 100 of the second embodiment, the data can be outputted with a delay time corresponding to a single stage only. Also, according to the second embodiment, the range of the clock signal CK is reduced, thus further reducing the power consumption.

The above-described second embodiment is merely exemplary, and it is understood by those skilled in the art that various modifications to the combination of each component and each process thereof are possible and that such modifications are also within the scope of the present invention.

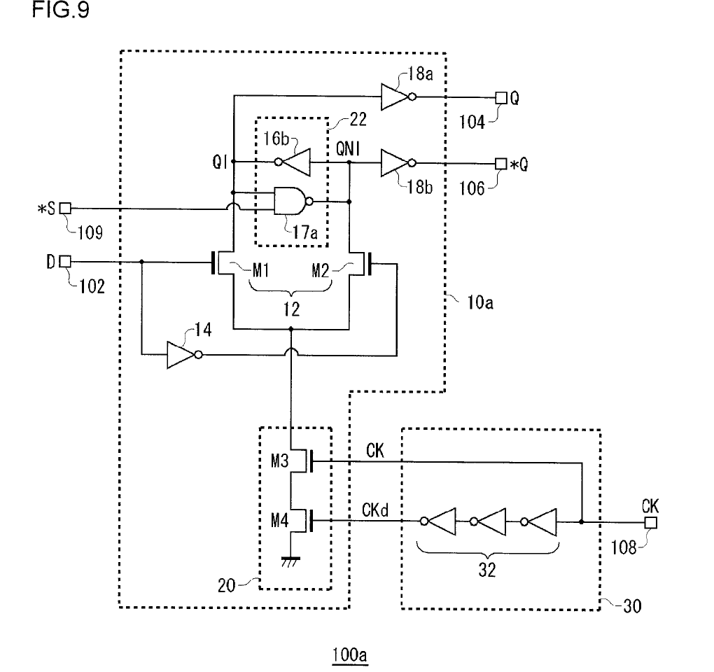

FIG. 9 is a circuit diagram showing a structure of a flip-flop circuit 10a according to a first modification of the second embodiment. For the first modification of the second embodiment, only points that differ from the flip-flop circuit 100 shown in FIG. 7 are described hereinbelow. The flip-flop circuit 100a includes a NAND gate 17a in place of the inverter 16a of FIG. 7. An internal signal QI is inputted to one terminal of the NAND gate 17a, whereas an inverted set signal *S is inputted to the other terminal of the NAND gate 17a via a set terminal 109.

For a period during which the inverted set signal *S inputted to the set terminal 109 is in a low level, an internal signal QNI is fixed to a high level regardless of the active/inactive state of the latch circuit 10a and the level of the input signal D. At this time, the internal signal QI is fixed to a low level. As a result, an output signal Q goes high and the inverted output signal *Q goes low.

When the inverted set signal *S is high, the NAND gate 17a achieves the same function as that of the internal inverter 16a in the flip-flop circuit 100 of FIG. 7, and the operation of the flip-flop circuit 10a is the same as that of FIG. 7.

Thus, for a period during which a high-level signal is inputted to the set terminal 109 as the inverted set signal *S, the flip-flop circuit 10a latches the input signal D based on a clock signal CK similarly to the timing chart shown in FIG. 8. As the inverted set signal *S transits from high to low at given time, the output signal Q is set to a high level and the inverted output signal *Q is set to a low level.

According to this first modification of the second embodiment, a setting function can be added to the flip-flop circuit of FIG. 7. Similar to the flip-flop circuit shown in FIG. 7, high speed, reduced power consumption and area saving can be achieved as compared with the conventional flip-flop circuits.

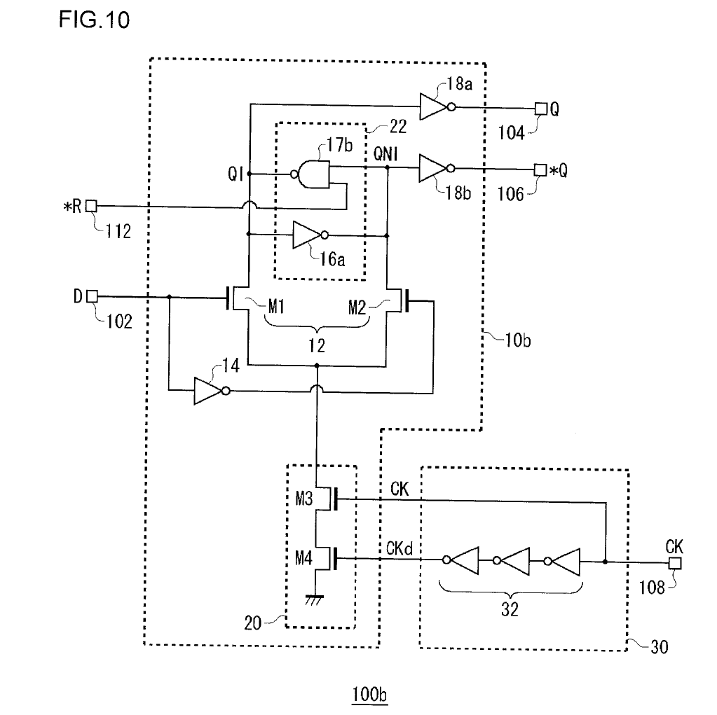

FIG. 10 is a circuit diagram showing a structure of a flip-flop circuit 100b according to a second modification of the second embodiment. This flip-flop circuit 100b includes a NAND gate 17b in place of the inverter 16b of FIG. 7. An internal signal QNI is inputted to one terminal of the NAND gate 17b, whereas an inverted reset signal *R is inputted to the other terminal of the NAND gate 17a via a reset terminal 112.

For a period during which the inverted reset signal *R is in a high level, the flip-flop circuit 100b, which operates the same way as in the timing chart of FIG. 8, latches the input signal D. As the inverted reset signal *R transits from high to low, the output signal Q is reset to a low level and the inverted output signal*Q is reset to a high level.

According to this second modification of the second embodiment, a resetting function can be added to the flip-flop circuit of FIG. 7. Similar to the flip-flop circuit shown in FIG. 7, high speed, reduced power consumption and area saving can be achieved as compared with the conventional flip-flop circuits.

In the second embodiment, a description has been given of a case where the amplitude of the clock signal CK supplied to the clock terminal 108 is reduced and narrowed. At the same time, the present invention is applicable to a circuit having the same amplitude as that of the first supply voltage supplied to the latch circuit 10 excluding the activation circuit 20. In such a case, it is only necessary to supply the first supply voltage to the inverters included in the delay circuit 32. Even in such a case, for only a predetermined period Tx starting from a positive edge of the clock signal CK, the transition of the input data D is retrieved as a level transition of the internal signals QI and QNI. Hence, similar to the flip-flop circuit of FIG. 7, high speed, reduced power consumption and area saving can be achieved.

In the flip-flop circuit 100 shown in FIG. 7, a description has been given of a case where the clock signal CK is inputted to the gate terminal of the first activation transistor M3, and the clock signal CKd is inputted to the gate terminal of the second activation transistor M4. This may be reversed. In such a case, too, both the first activation transistor M3 and the second activation transistor M4 turn on for a period during which the clock signals CK and CKd are both high, so that the same operation as that of the flip-flop circuit 100 of FIG. 7 can be realized.

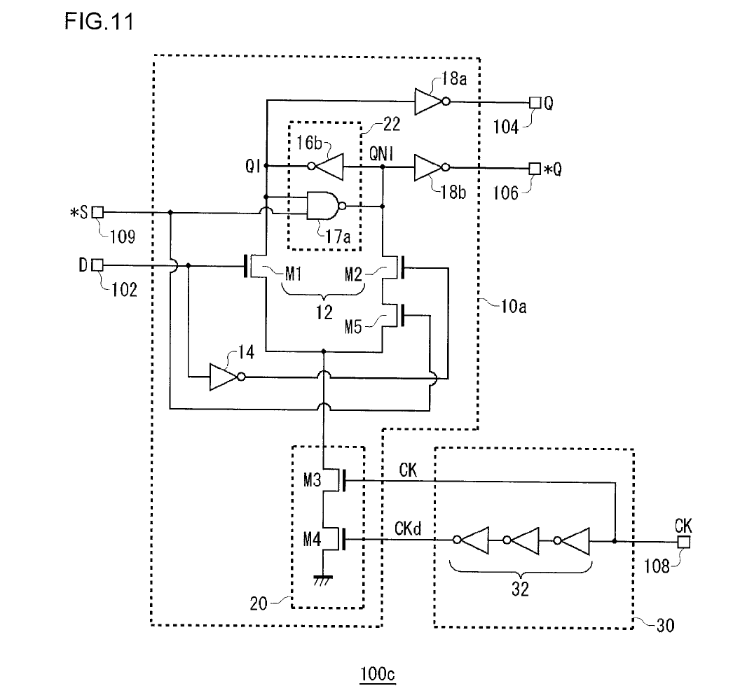

FIG. 11 is a circuit diagram showing a structure of a flip-flop circuit 100c according to a modification of the flip-flop circuit 10a shown in FIG. 9. The flip-flop circuit 100c as shown in FIG. 11 is configured such that a third input transistor M5 is added to the flip-flop circuit 100a shown in FIG. 9. A source terminal of the third input transistor M5 is connected to a drain terminal of a first activation transistor M3, and a drain terminal of the third input transistor M5 is connected to a source terminal of the second input transistor M2. An inverted set signal *S inputted to a set terminal 109 is inputted to a gate terminal of the third input transistor M5. According to this modification, the third input transistor M5 turns off for a period during which the inverted set signal *S is in a low level, so that an internal signal QNI can be reliably set to a high level regardless of the level of an input signal D.

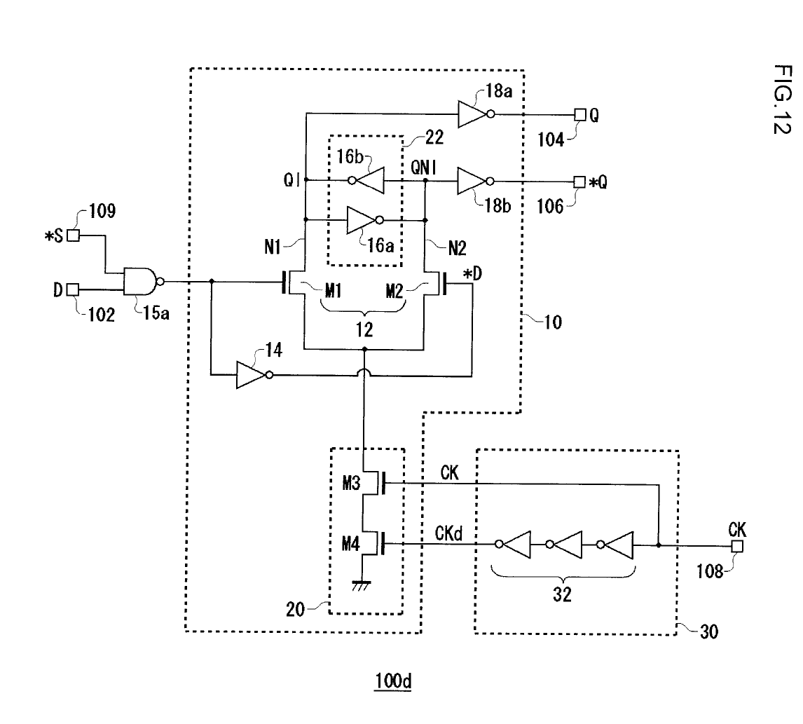

FIG. 12 is a circuit diagram showing a structure of a flip-flop circuit 100d according to a modification of the flip-flop circuits 100 and 100a shown in FIG. 7 and FIG. 9. The flip-flop circuit 100d as shown in FIG. 12 is configured such that a set terminal 109 and a NAND gate 15a are added to the flip-flop circuit 100 shown in FIG. 7. Input data D inputted to an input terminal 102 and an inverted set signal *S inputted to the set terminal 109 are inputted to the NAND gate 15a. An output signal of the NAND gate 15a is inputted to a gate terminal of a first input transistor M1 and an input inverter 14.

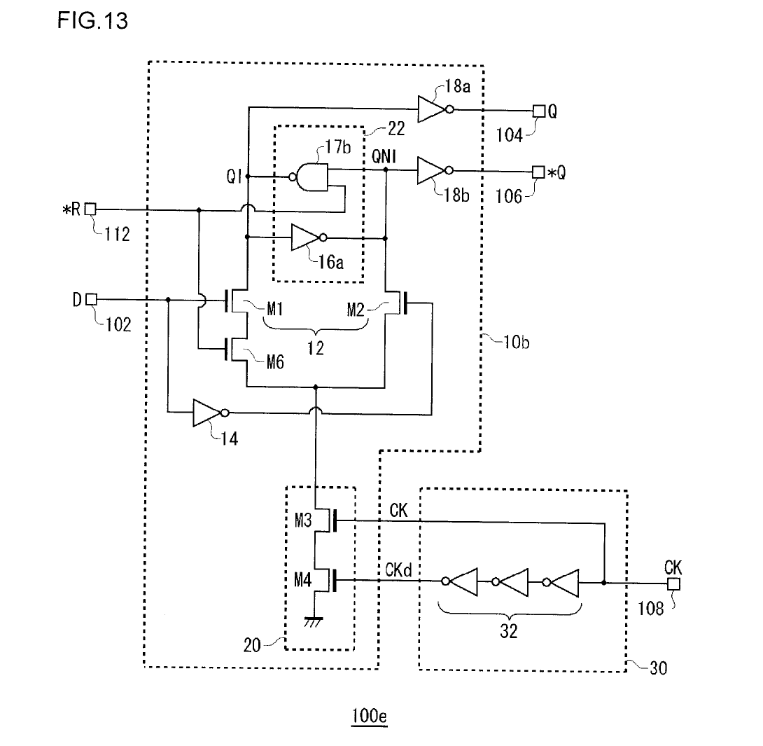

FIG. 13 is a circuit diagram showing a structure of a flip-flop circuit 10e according to a modification of a flip-flop circuit 100b shown in FIG. 10. The flip-flop circuit 10e as shown in FIG. 13 is configured such that a fourth input transistor M6 is added to the flip-flop circuit 100b shown in FIG. 10. A source terminal of the fourth input transistor M6 is connected to a drain terminal of the first activation transistor M3, and a drain terminal of the fourth input transistor M6 is connected to a source terminal of a first input transistor M1. An inverted reset signal *R inputted to a reset terminal 112 is inputted to a gate terminal of the fourth transistor M6. According to this modification, the fourth input transistor M6 turns off for a period during which the inverted reset signal *R is in a low level, so that an internal signal QI can be reliably set to a high level regardless of the level of an input signal D.

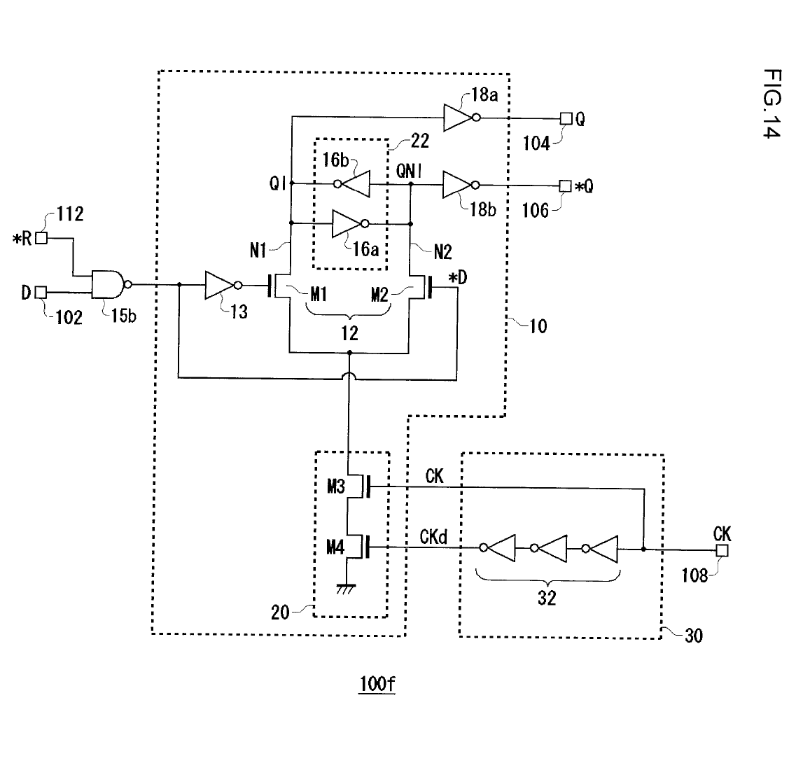

FIG. 14 is a circuit diagram showing a structure of a flip-flop circuit 100f according to a modification of flip-flop circuits 100 and 100b shown in FIG. 7 and FIG. 10. The flip-flop circuit 100f as shown in FIG. 14 is configured such that a reset terminal 112 and a NAND gate 15b are added to the flip-flop circuit 100 shown in FIG. 7. Also, the input inverter 14 for inverting the data inputted to the gate terminal of the second input transistor M2 is not provided and an input inverter 13 for inverting the data inputted to a gate terminal of a first input transistor M1 is provided. Input data D inputted to an input terminal 102 and an inverted reset signal *R inputted to a reset terminal 112 are inputted to the NAND gate 15b. An output signal of the NAND gate 15b is inputted to the input inverter 13 and the second input transistor M2.

In the flip-flop circuit 100 of the second embodiment, transistors structured by N-channel MOSFETs may be structured by P-channel MOSFETs. In such a case, a high and a low level of a signal fed to a gate thereof may be inverted as appropriate. In a preferred embodiment, the clock signals CK and CKb may be set in a manner such that a narrower range of voltage between a second ground voltage higher than a first ground voltage supplied to the flip-flop circuit and a first supply voltage supplied to the flip-flop circuit is set and the second ground voltage is supplied to an inverter included in the delay circuit 32. Also, a control may be performed in such a manner that the amplitudes of the clock CK and CKd are varied in accordance with the intended use or purpose such as operation speed and reduced power consumption.

While the preferred embodiments of the present invention have been described using specific terms, such description is for illustrative purposes only, and it is to be understood that changes and variations may be made without departing from the spirit or scope of the appended claims.

What is claimed is:

1. A flip-flop circuit, including a latch circuit which latches input data based on a first clock,
wherein said latch circuit take in the input data in a period of a phase difference between the first clock and a second clock whose phase differs from that of the first clock.

2. A flip-flop circuit according to claim 1, wherein said latch circuit includes a pair of transistors to which the input data and a signal obtained by inverting the input data are inputted,
wherein the pair of transistors are activated in the period of the phase difference.

3. A flip-flop circuit, including:
a first latch circuit which latches input data based on a first clock; and
a second latch circuit which latches the data latched by said first latch circuit and which generates output data,
wherein said first latch circuit is activated in a period of a phase difference between the first clock and a second clock whose phase differs from that of the first clock, and takes in the input data, and
wherein said second latch circuit latches the data latched by said first latch circuit at the time when said first latch circuit is inactive.

4. A flip-flop circuit according to claim 1, further including a control circuit which includes a plurality of stages of inverters connected in series with each other wherein the first clock is inputted to a first-stage inverter and an output of a final-stage inverter is outputted as the second clock.

5. A flip-flop circuit according to claim 3, further including a control circuit which includes a plurality of stages of inverters connected in series with each other wherein the first clock is inputted to a first-stage inverter and an output of a final-stage inverter is outputted as the second clock.

6. A flip-flop circuit for latching input data based on a clock signal, the circuit comprising:
a pair of transistors which receive an input of signals of the input data and the inverted input data;
an activation circuit which activates said pair of transistors in a conduction state; and
a control circuit which receives the clock signal and sets said activation circuit to a conduction state for a predetermined period starting from an edge timing of the clock signal.

7. A flip-flop circuit according to claim 6, wherein said activation circuit includes a first activation transistor and a second activation transistor which are connected in cascade between source terminals of said pair of transistors and fixed potential,
wherein said control circuit turns on both the first activation transistor and the second transistor for the predetermined period starting from the edge timing of the clock signal, and turns off at least one of the first activation transistor and the second activation transistor for a period other than the predetermined period.

8. A flip-flop circuit according to claim 6, wherein said activation circuit includes: a first activation transistor provided between source terminals of said pair of transistors and fixed potential; and a second activation transistor provided in a side of drain terminals of said pair of transistors,
wherein said control circuit turns on both the first activation transistor and the second transistor for the predetermined period starting from the edge timing of the clock signal, and turns off at least one of the first activation transistor and the second activation transistor for a period other than the predetermined period.

9. A flip-flop circuit according to claim 7, wherein said control circuit includes a delay circuit which delays the clock signal by a predetermined delay time, and
wherein an on-off of one of the first activation transistor and the second activation transistor is associated with the clock signal, and an on-off of the other thereof is associated with the delayed clock signal.

10. A flip-flop circuit according to claim 8, wherein said control circuit includes a delay circuit which delays the clock signal by a predetermined delay time, and
wherein an on-off of one of the first activation transistor and the second activation transistor is associated with the clock signal, and an on-off of the other thereof is associated with the delayed clock signal.

11. A flip-flop circuit according to claim 9, wherein the delay circuit includes a plurality of stages of inverters.

12. A flip-flop circuit according to claim 10, wherein the delay circuit includes a plurality of stages of inverters.

13. A flip-flop circuit according to claim 9, a narrower range is specified by setting the level of a second supply voltage lower than the level of a first supply voltage supplied to said flip-flop circuit, and second supply voltage is supply to the delay circuit.

14. A flip-flop circuit according to claim 10, a narrower range is specified by setting the level of a second supply voltage lower than the level of a first supply voltage supplied to said flip-flop circuit, and second supply voltage is supply to the delay circuit.

15. A flip-flop circuit according to claim 1, a narrower range is specified by setting the first clock and the second clock to the level of a second supply voltage lower than the level of a first supply voltage supplied to said flip-flop circuit.

16. A flip-flop circuit according to claim 3, a narrower range is specified by setting the first clock and the second clock to the level of a second supply voltage lower than the level of a first supply voltage supplied to said flip-flop circuit.
